(19) United States
(12) Patent Application Publication
(10) Pub. No.: US 2024/0222929 A1
(43) Pub. Date: Jul. 4, 2024

(54) OPTICAL COMMUNICATION DEVICE

(71) Applicant: Electronics and Telecommunications Research Institute, Daejeon (KR)

(72) Inventors: Young-Tak HAN, Daejeon (KR); Seok Jun YUN, Daejeon (KR); Seo Young LEE, Daejeon (KR); Sang Ho PARK, Daejeon (KR); Yongsoon BAEK, Daejeon (KR); Jang Uk SHIN, Daejeon (KR); Dong-Hun LEE, Daejeon (KR)

(73) Assignee: Electronics and Telecommunications Research Institute, Daejeon (KR)

(21) Appl. No.: 18/496,613

(22) Filed: Oct. 27, 2023

(30) Foreign Application Priority Data
Jan. 3, 2023 (KR) 10-2023-0000888

(51) Int. Cl. H01S 5/0233; H01S 5/02315; H01S 5/026

(52) U.S. Cl. CPC H01S 5/0233; H01S 5/02315; H01S 5/0265; H01S 5/12

(57) ABSTRACT

Provided is an optical communication device according to an embodiment of the inventive including a carrier substrate, a printed circuit board provided on one side of the carrier substrate in a first direction, electro-absorption modulator-integrated laser chips provided on the other side of the carrier substrate, an interposer provided on the electro-absorption modulator-integrated laser chips and the printed circuit board, and capacitors, which are provided on the interposer and each of which is shorter than each of the electro-absorption modulator-integrated laser chips and is thicker than the electro-absorption modulator-integrated laser chip.

### CROSS-REFERENCE TO RELATED APPLICATIONS

This U.S. non-provisional patent application claims priority under 35 U.S.C. § 119 of Korean Patent Application No. 10-2023-0000888, filed on Jan. 3, 2023, the entire contents of which are hereby incorporated by reference.

### BACKGROUND

The present disclosure herein relates to an optical communication device, and more particularly, to an optical communication device capable of achieving a communication at a high speed of about 100 Gbps or higher per channel.

In general, an electro-absorption modulator-integrated laser (EML) is constituted by parts, a distributed feedback laser diode (DFB-LD) and an electro-absorption modulator (EAM). The DFB-LD performs a function to output continuous wave (CW) light, and the EAM performs a function to modulate the output CW light in a high frequency band. In order to modulate the CW light at a high frequency band, an EAM portion connected to a transmission line needs to be terminated with a 50-ohm resistor so that a high frequency signal is effectively transmitted to the EAM. The EAM is an element, which operates in a state in which a reverse bias voltage is applied thereto, and has a very high resistance value when operating in a reverse bias. Accordingly, a resistor of about 50 ohms needs to be connected in parallel to the EAM.

### SUMMARY

The present disclosure provides an optical communication device capable of minimizing a size or an area of an element.

An embodiment of the inventive concept provides an optical communication device. The optical communication device includes a carrier substrate, a printed circuit board provided on one side of the carrier substrate in a first direction, electro-absorption modulator-integrated laser chips provided on the other side of the carrier substrate, an interposer provided on the electro-absorption modulator-integrated laser chips and the printed circuit board, and capacitors provided on the interposer, the capacitors shorter than the electro-absorption modulator-integrated laser chips and thicker than the electro-absorption modulator-integrated laser chips.

In an embodiment, the electro-absorption modulator-integrated laser chips may be aligned with the capacitors in a second direction crossing the first direction.

In an embodiment, each of the electro-absorption modulator-integrated laser chips and the capacitors may have a width of 100 μm to 400 μm in the second direction.

In an embodiment, the width of each of the electro-absorption modulator-integrated laser chip may be 200 μm.

In an embodiment, the electro-absorption modulator-integrated laser chips may be arranged to have a pitch that is two times or more than the width of each of the electro-absorption modulator-integrated laser chips.

In an embodiment, the pitch between the electro-absorption modulator-integrated laser chips may be 400 μm or greater.

In an embodiment, a distance between the electro-absorption modulator-integrated laser chips may be 200 μm or greater.

In an embodiment, each of the electro-absorption modulator-integrated laser chips may include an element substrate, an optical waveguide provided on the element substrate and extending in one direction, a laser source (DFB-LD) provided on one side of the element substrate and connected to the optical waveguide, and a (electro-absorption) modulator provided on the other side of the element substrate and connected to the optical waveguide.

In an embodiment, each of the electro-absorption modulator-integrated laser chips may further include a detector (monitoring PD (MPD)) that is provided to be adjacent to the laser source and detects laser light in the optical waveguide.

In an embodiment, the interposer may include a first via electrode connected to the laser source, a second via electrode connected to the modulator, a third via electrode connected to the detector, and a fourth via electrode connected to a ground line of the printed circuit board.

In an embodiment, the optical communication device may further include thin film resistors, each of which is provided between the capacitors and connected to the second via electrode.

In an embodiment, the optical communication device may further include bonding wires, each of which is connected between the thin film resistor and the capacitor.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view illustrating an example of an optical communication device according to an embodiment of the inventive concept;

FIG. 2 is a perspective view illustrating portion A in FIG. 1;

FIG. 3 is a cross-sectional view taken along line I-I′ in FIG. 2;

FIG. 4 is a plan view illustrating an example of an electro-absorption modulator-integrated laser chip in FIG. 1;

FIGS. 5 to 8 are perspective and plan views illustrating an example of an interposer in FIG. 1;

FIG. 9 is a cross-sectional view illustrating an example of a first via electrode, a second via electrode, a third via electrode, and a fourth via electrode of the interposer in FIG. 5;

FIG. 10 is a perspective view illustrating an example of a capacitor in FIG. 1;

FIG. 11 is a cross-sectional view taken along line II-II′ in FIG. 3; and

FIG. 12 is a graph illustrating electrical crosstalk according to a distance between electro-absorption modulator-integrated laser chips in FIG. 11.

### DETAILED DESCRIPTION

Hereinafter, embodiments of the inventive concept will be described in detail with reference to the accompanying drawings. Advantages and features of the present invention, and implementation methods thereof will be clarified through following embodiments described in detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

The terminology used herein is for the purpose of describing embodiments only and is not intended to be limiting of the invention. As used herein, the singular forms are intended to include the plural forms as well, unless the context clearly indicates otherwise. It will be understood that the terms “comprises” and/or “comprising”, when used in this specification, specify the presence of stated components, steps, operations, and/or elements, but do not preclude the presence or addition of one or more other components, steps, operations, and/or elements. It will be further understood that laser, a modulator, an interposer, or a board used herein has a meaning commonly used in the field of optical communications. Since the following description is provided according to preferred embodiments, the order of the reference numerals given in the description below is not necessarily limited thereto.

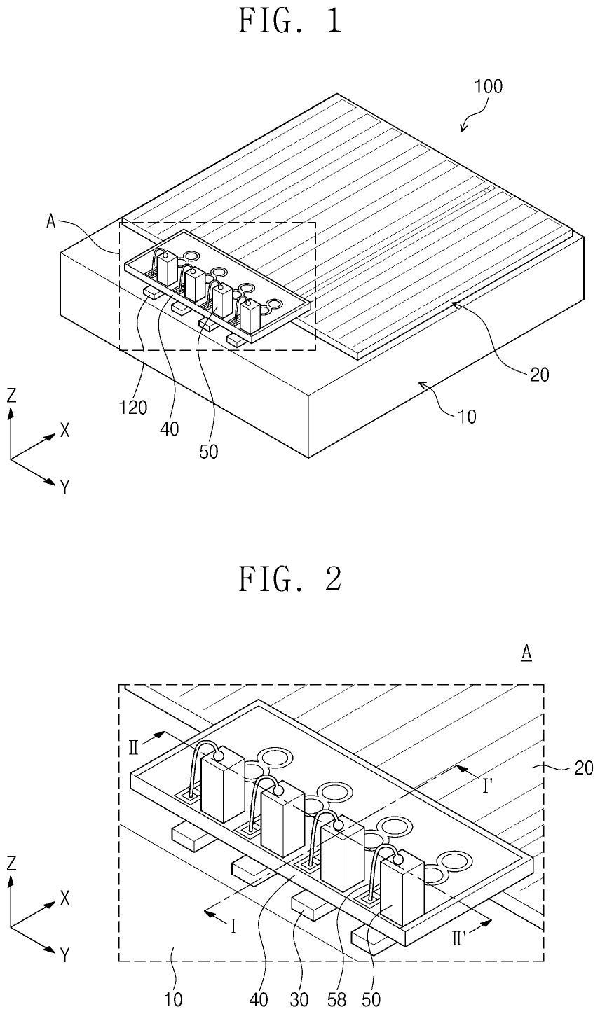

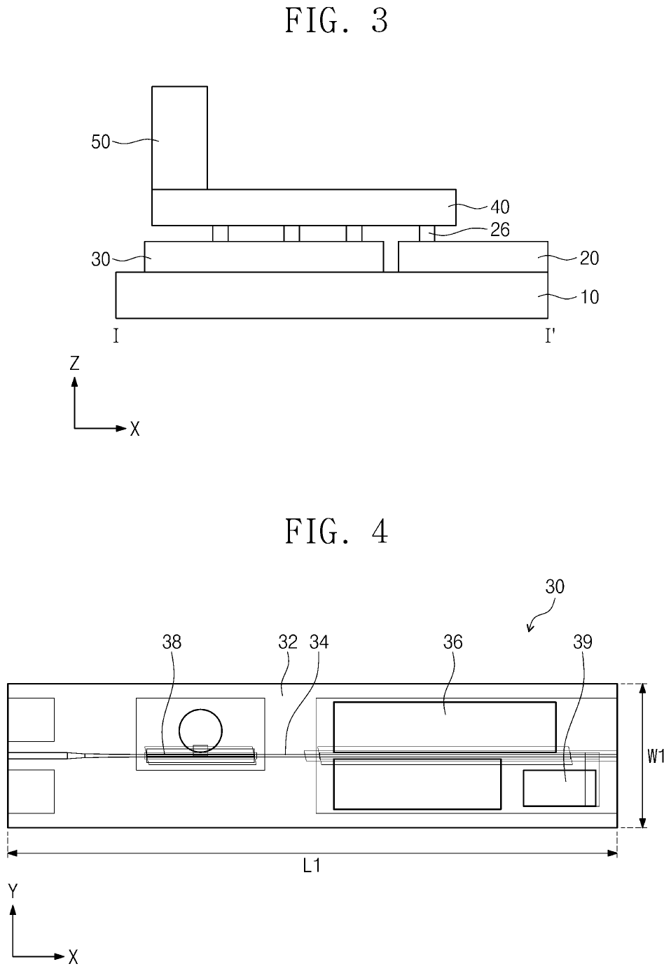

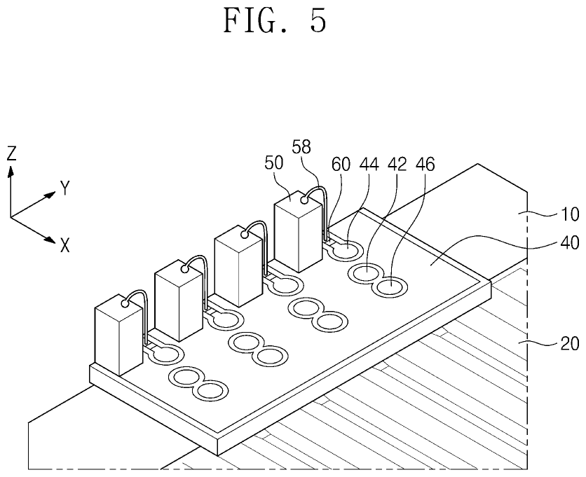

FIG. 1 illustrates an example of an optical communication device 100 according to an embodiment of the inventive concept. FIG. 2 illustrates portion A in FIG. 1. FIG. 3 illustrates a cross section taken along line I-I′ in FIG. 2.

Referring to FIGS. 1 to 3, the optical communication device 100 according to an embodiment of the inventive concept may include an optical transmitter. According to an embodiment, the optical communication device 100 according to an embodiment of the inventive concept may include a carrier substrate 10, a printed circuit board 20, electro-absorption modulator-integrated laser chips 30, an interposer 40, capacitors 50, and a thin film resistor 60.

The carrier substrate 10 may support the printed circuit board 20 and the electro-absorption modulator-integrated laser chips 30. The carrier substrate 10 may include a silicon substrate.

The printed circuit board 20 may be provided on one side of the carrier substrate 10 in a first direction X. The printed circuit board 20 may be connected to the interposer 40 by a lower Au bump 26 or a solder ball. The printed circuit board 20 may include a flexible printed circuit board.

The electro-absorption modulator-integrated laser chips 30 may be provided on the other side of the carrier substrate 10 in the first direction X. Each of the electro-absorption modulator-integrated laser chips 30 may have the same thickness as the printed circuit board 20. The electro-absorption modulator-integrated laser chips 30 may be connected to the interposer 40 by the lower bumps 26 or the solder balls. Each of the lower bumps 26 or the solder balls may have a diameter of about 30 μm to about 60 μm. The electro-absorption modulator-integrated laser chips 30 may be connected to the interposer 40 through silver pastes, AgSnCu solder pastes, or AuSn solders, and an embodiment of the inventive concept is not limited thereto. The electro-absorption modulator-integrated laser chips 30 may output an optical signal modulated in response to an electrical (RF) signal transmitted through the printed circuit board. Each of the electro-absorption modulator-integrated laser chips 30 may be a lumped electro-absorption modulator-integrated laser chip. The electro-absorption modulator-integrated laser chips 30 may be provided in four, eight, sixteen or more to be arranged. Each of the electro-absorption modulator-integrated laser chips 30 may operate at high frequency and a high speed of 100 Gbps per channel. The electro-absorption modulator-integrated laser chips 30 may each improve high frequency characteristics without signal interference (electrical crosstalk) therebetween.

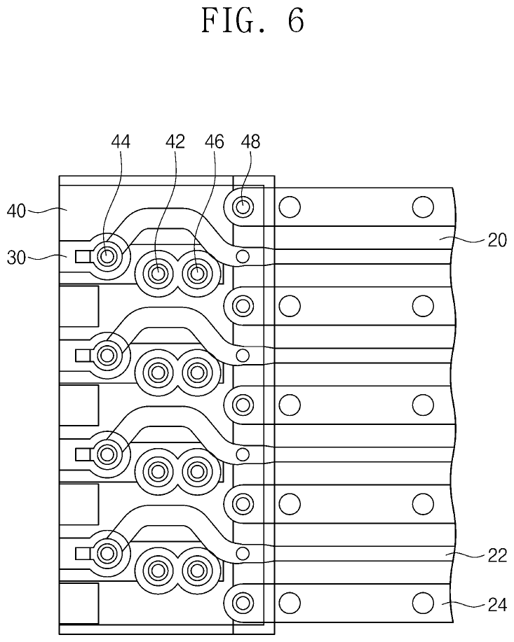

FIG. 4 illustrates an example of the electro-absorption modulator-integrated laser chip 30 in FIG. 1.

Referring to FIG. 4, the electro-absorption modulator-integrated laser chip 30 may include an element substrate 32, an optical waveguide 34, a laser source 36, a modulator 38, and a detector 39.

The element substrate 32 may support the optical waveguide 34, the laser source 36, the modulator 38, and the detector 39. The element substrate 32 may include a silicon substrate. Alternatively, the element substrate 32 may include a III-V semiconductor, and an embodiment of the inventive concept is not limited thereto. The element substrate 32 may have a rectangular shape when viewed on a plan view. The element substrate 32 may have a first length L1 and a first width W1. The first length L1 may be defined as a length in a direction of the optical waveguide 34. The first length L1 may be about 0.5 mm to about 2 mm. The first width W1 may be defined as a width in a direction perpendicular to the optical waveguide 34. The first width W1 may be less than about 500 μm. The first length W1 may be about 100 μm to about 400 μm. The first width W1 may be about 200 μm.

The optical waveguide 34 may be provided on the element substrate 32 to extend in the first direction X. The optical waveguide 34 may include a ridge waveguide. The optical waveguide 34 may transmit laser light to an external optical fiber or a planar lightwave circuit.

The laser source 36 may be provided on one side of the element substrate 32 in the first direction X. The laser source 36 may be connected to the optical waveguide 34. The laser source 36 may generate the laser light. The laser light may be a continuous wave. The laser source 36 may include a distributed feedback laser diode (DFB-LD).

The modulator 38 may be provided on the other side of the element substrate 32 in the first direction X. The modulator 38 may be connected to the optical waveguide 34 to modulate the laser light. The laser light may have a pulse signal. The modulator 38 may be an electro-absorption modulator (EAM).

The detector 39 may be provided to be adjacent to the laser source 36. The detector 39 may detect the laser light in the optical waveguide 34. The detector 39 may include a monitoring photo-sensor (photodiode).

Referring to FIGS. 1 to 3 again, the interposer 40 may be provided on the printed circuit board 20 and the electro-absorption modulator-integrated laser chips 30. The interposer 40 may connect the printed circuit board 20 to the electro-absorption modulator-integrated laser chips 30. The interposer 40 may connect the capacitors 50 and the thin film resistor 60 to the electro-absorption modulator-integrated laser chips 30. The interposer 40 may have a thickness of about 50 μm to about 150 μm. The interposer 40 may include silicon or ceramics (e.g., Al₂O₃ or AlN). The interposer 40 made of a silicon material may have a thickness of about 50 μm to about 100 μm, and the interposer 40 made of a ceramic material may have a thickness of about 100 μm to about 150 μm. The interposer 40 may improve heat dissipation of the electro-absorption modulator-integrated laser chips 30. Although not illustrated, the interposer 40 may have a ground electrode GND exposed to a top surface thereof.

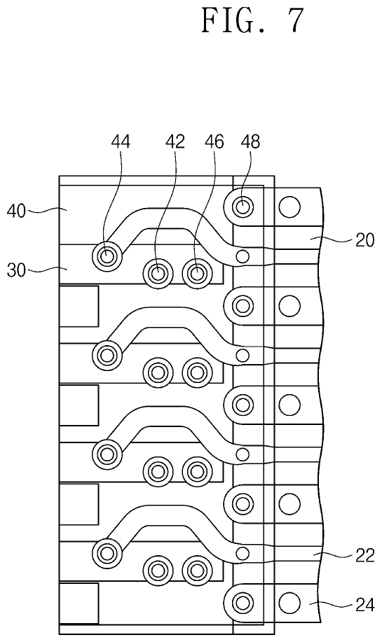

FIGS. 5 to 8 illustrate an example of the interposer 40 in FIG. 1.

Referring to FIGS. 5 to 8, the interposer 40 may include a first via electrode 42, a second via electrode 44, a third via electrode 46, and a fourth via electrode 48. The first via electrode 42 may be a signal electrode connected to the laser source 36. The second via electrode 44 may be a signal (RF) electrode connected to the modulator 38. The second via electrode 44 may be connected to the thin film resistor 60. The third via electrode 46 may be a signal (DC) electrode connected to the detector 39. The first via electrode 42, the second via electrode 44, and the third via electrode 46 may be separated from a ground electrode. The fourth via electrode 48 may be the ground electrode GND. The fourth via electrode 48 may be connected to the ground electrode.

The printed circuit board 20 may include signal lines 22 and ground lines 24. The signal lines 22 and the ground lines 24 may be arranged alternately with each other. The signal lines 22 may be connected to the second via electrode 44.

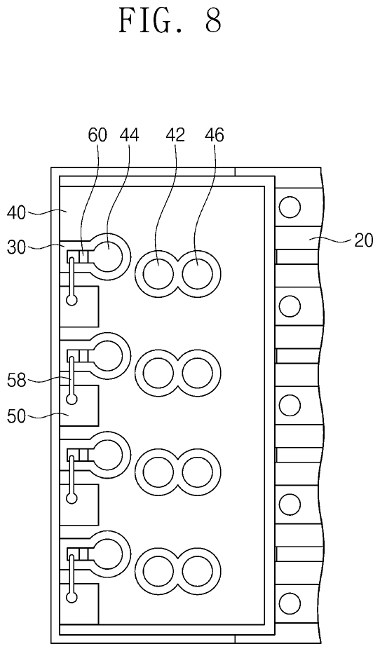

FIG. 9 illustrates an example of the first via electrode 42, the second via electrode 44, the third via electrode 46, and the fourth via electrode 48 of the interposer 40 in FIG. 5.

Referring to FIGS. 5 to 9, each of the first via electrode 42, the second via electrode 44, the third via electrode 46, and the fourth via electrode 48 may be connected to the electro-absorption modulator-integrated laser chip 30 or the printed circuit board 20 by the lower bumps 26.

A plurality of thin film resistors 60 may be provided on the top surface of the interposer 40. The thin film resistors 60 may be separated from the ground electrode of the interposer 40. Each of the thin film resistors 60 may be connected to the second via electrode 44 and a bonding wire 58. Each of the thin film resistors 60 may have a thickness of about 0.1 μm to about 1 μm. Each of the thin film resistors 60 may be smaller or narrower than the capacitors 50 and the second via electrode 44 when viewed on a plan view. Each of the thin film resistors 60 may be deposited to have a thin-film shape by using a NiCr or TaN material. The capacitors 50 may be mounted on the ground electrode of the interposer 40 to achieve 2.5 D impedance matching of the optical communication device 100.

Referring to FIGS. 1 to 9, the capacitors 50 may be provided on the interposer 40. The capacitors 50 may induce an LC resonance effect of the optical communication device 100 together with an inductance (L) of the bonding wire 58. The electro-absorption modulator-integrated laser chips 30 and the capacitors 50 may be disposed in a one-to-one correspondence. For example, the capacitors 50 may include a multilayer ceramic capacitor (MLCC). Each of the capacitors 50 may have a capacitance of about 0.1 μF. That is, the capacitors 50 may be SMD type capacitors (AC-coupling & DC-blocking capacitors). Each of the capacitors 50 may transmit a high-frequency signal and block DC optical current flowing through the modulator 38.

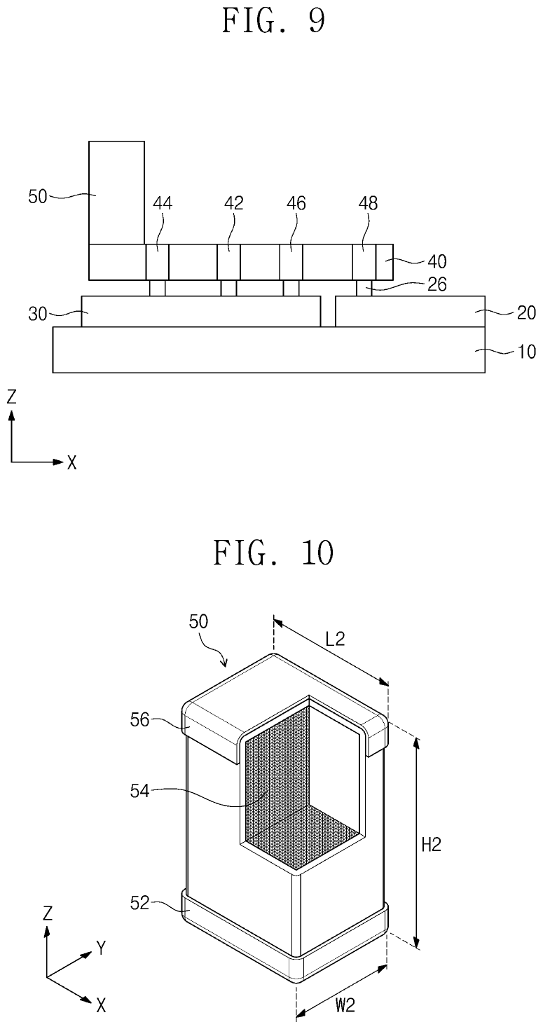

FIG. 10 illustrates an example of the capacitor 50 in FIG. 1.

Referring to FIG. 10, the capacitor 50 may have a rectangular parallelepiped shape. The capacitor 50 may include a lower electrode 52, a stack structure 54, and an upper electrode 56.

The lower electrode 52 may be provided between the interposer 40 and the stack structure 54. The lower electrode 52 may be connected to the interposer 40.

The stack structure 54 may be provided between the lower electrode 52 and the upper electrode 56. The stack structure 54 may include metal plates and dielectrics. The metal plates and the dielectrics may be arranged alternately with each other. The metal plates may include a nickel-copper alloy. The dielectrics may include BaTiO₃. Each of the metal plates and the dielectrics may have a thickness of about 300 nm to about 400 nm. Each of the metal plates and the dielectrics may include about 90 layers.

The upper electrode 56 may be provided on the stack structure 54. The upper electrode 56 may be connected to a pad of the thin film resistor 60 through a bonding wire 58. The bonding wire 58 may have a length that is determined according to wideband high-frequency characteristics due to the LC resonance effect. For example, the length of the bonding wire 58 may be about 300 μm to about 800 μm.

According to an embodiment, the capacitor 50 may have a second length L2, a second width W2, and a second height H2. The second length L2 may be the same as the second width W2 and less than the second height H2. The second length L2 may be about 200 μm to about 300 μm. The second width W2 may be about 200 μm to about 300 μm. The second height H2 may be about 400 μm to about 600 μm.

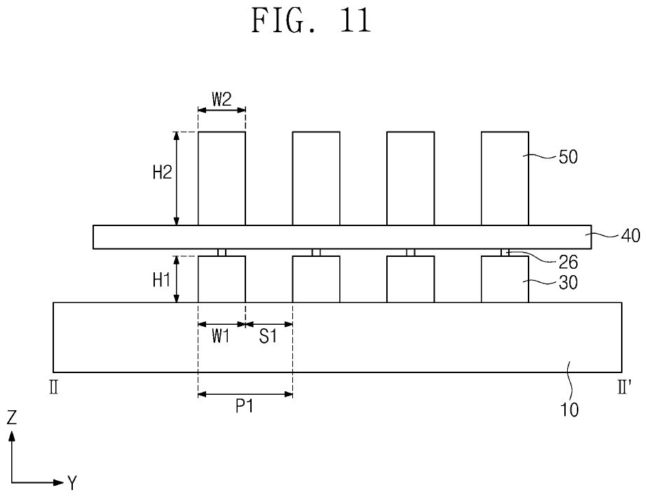

FIG. 11 illustrates a cross section taken along line II-II′ in FIG. 3.

Referring to FIG. 11, the capacitors 50 may be aligned in a second direction Y on the electro-absorption modulator-integrated laser chips 30 so as to correspond thereto. A distance between the electro-absorption modulator-integrated laser chips 30 may be the same as the first width W1 of each of the electro-absorption modulator-integrated laser chips 30. The electro-absorption modulator-integrated laser chips 30 may have a pitch P1 that is about 2 to about 2.5 times the first width W1. The capacitors 50 may have the same pitch as the pitch P1 of the electro-absorption modulator-integrated laser chips 30.

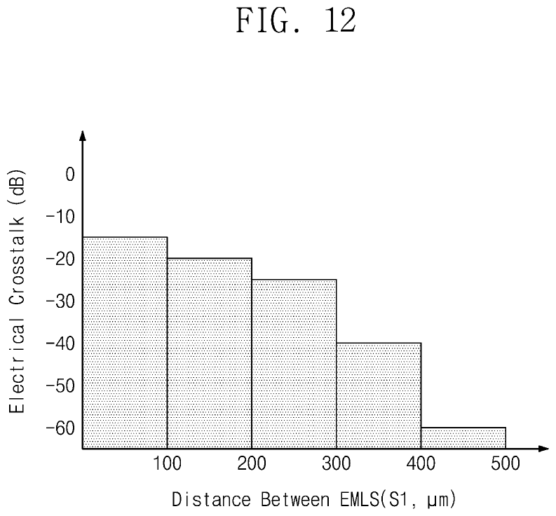

FIG. 12 illustrates electrical crosstalk according to the distance between the electro-absorption modulator-integrated laser chips 30 in FIG. 11.

Referring to FIGS. 11 and 12, when a distance S1 between the electro-absorption modulator-integrated laser chips 30 is less than about 200 μm, the electrical crosstalk increases to about −20 dB or greater, and thus, the high-frequency operation characteristic and reliability of the optical communication device 100 may deteriorate.

When the distance S1 between the electro-absorption modulator-integrated laser chips 30 is about 200 μm to about 300 μm, the electrical crosstalk decreases to about −20 dB, and thus, the high-frequency operation characteristic and reliability of the optical communication device 100 may increase. When the first width W1 of each of the electro-absorption modulator-integrated laser chips 30 is about 200 μm, the pitch P1 between the electro-absorption modulator-integrated laser chips 30 may be about 400 μm to about 500 μm.

When the distance S1 between the electro-absorption modulator-integrated laser chips 30 is greater than about 300 μm, the electrical crosstalk decreases to about −40 dB or less, and thus, the high-frequency operation characteristic and the reliability of the optical communication device 100 may be very excellent.

Therefore, the optical communication device 100 according to an embodiment of the inventive concept may use the electro-absorption modulator-integrated laser chips 30 and the capacitors 50, which are aligned below and above the interposer 40, respectively, thereby minimizing the area and the size of a multi-channel optical transmitter module.

As described above, an optical communication device according to an embodiment of the inventive concept may minimize an area and a size of a multi-channel optical transmitter module by using electro-absorption modulator-integrated laser chips and capacitors that are aligned below and above an interposer, respectively.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. An optical communication device comprising:
a carrier substrate;
a printed circuit board provided on one side of the carrier substrate in a first direction;
electro-absorption modulator-integrated laser chips provided on the other side of the carrier substrate;
an interposer provided on the electro-absorption modulator-integrated laser chips and the printed circuit board; and
capacitors provided on the interposer, the capacitors shorter than the electro-absorption modulator-integrated laser chips and thicker than the electro-absorption modulator-integrated laser chips.

2. The optical communication device of claim 1, wherein the electro-absorption modulator-integrated laser chips are aligned with the capacitors in a second direction crossing the first direction.

3. The optical communication device of claim 2, wherein each of the electro-absorption modulator-integrated laser chips and the capacitors has a width of 100 μm to 400 μm in the second direction.

4. The optical communication device of claim 3, wherein the width of each of the electro-absorption modulator-integrated laser chips is 200 μm.

5. The optical communication device of claim 4, wherein the electro-absorption modulator-integrated laser chips are arranged to have a pitch that is 2 to 2.5 times the width of each of the electro-absorption modulator-integrated laser chips.

6. The optical communication device of claim 5, wherein the pitch between the electro-absorption modulator-integrated laser chips is 400 μm to 500 μm.

7. The optical communication device of claim 5, wherein a distance between the electro-absorption modulator-integrated laser chips is 200 μm to 300 μm.

8. The optical communication device of claim 1, wherein each of the electro-absorption modulator-integrated laser chips comprises:
an element substrate;
an optical waveguide provided on the element substrate and extending in one direction;
a laser source provided on one side of the element substrate and connected to the optical waveguide; and
a modulator provided on the other side of the element substrate and connected to the optical waveguide.

9. The optical communication device of claim 8, wherein each of the electro-absorption modulator-integrated laser chips further comprises a detector provided to be adjacent to the laser source and configured to detect laser light in the optical waveguide.

10. The optical communication device of claim 9, wherein the interposer comprises:
a first via electrode connected to the laser source;
a second via electrode connected to the modulator;
a third via electrode connected to the detector; and
a fourth via electrode connected to a ground line of the printed circuit board.

11. The optical communication device of claim 10, further comprising thin film resistors, each of which is provided between the capacitors and connected to the second via electrode.

12. The optical communication device of claim 11, further comprising a bonding wire connected between the thin film resistor and the capacitor.
